(19) United States
(12) Patent Application Publication
(10) Pub. No.: US 2010/0103805 A1
(43) Pub. Date: Apr. 29, 2010

(54) SEMICONDUCTOR LASER DRIVING DEVICE, OPTICAL HEAD DEVICE AND OPTICAL INFORMATION RECORDING/REPRODUCING DEVICE

(76) Inventors: Hiroaki Yoshida, Osaka (JP); Hideki Hayashi, Nara (JP); Tomotada Kamei, Osaka (JP)

Correspondence Address: MARK D. SARALINO (PAN);RENNER, OTTO, BOISSELLE & SKLAR, LLP, 1621 EUCLID AVENUE, 19TH FLOOR, CLEVELAND, OH, 44115, US

(21) Appl. No.: 11/997,330

(22) PCT Filed: Sep. 19, 2006
(86) PCT No.: PCT/JP2006/318510

§ 371 Date: Jan. 30, 2008

(30) Foreign Application Priority Data
Sep. 22, 2005 (JP) 2005-275699

(51) Int. Cl. G11B 7/00; H01S 5/068

(52) U.S. Cl. 369/121; 372/38.02; G9B/7

(57) ABSTRACT

A semiconductor laser driving device is provided with a high frequency superimposing circuit (3) for superimposing a frequency current onto a laser driving current (6) of a semiconductor laser (1) provided in an optical head device; and a high frequency superimposition control circuit (5) which controls the frequency of the high frequency current corresponding to the temperature of the semiconductor laser (1).

### TECHNICAL FIELD

The present invention relates to a semiconductor laser driver for controlling the output power of a semiconductor laser diode (LD), an optical head unit including such a driver, and an optical information processor that uses such an optical head unit.

### BACKGROUND ART

Data stored on an optical disk can be read out from the disk by irradiating the rotating disk with a relatively weak light beam with a constant intensity, and detecting the light that has been modulated by, and reflected from, the optical disk.

On a read-only optical disk, information is already stored as pits that are arranged spirally during the manufacturing process of the optical disk. On the other hand, on a rewritable optical disk, a recording material film, from/on which data can be read and written optically, is deposited by an evaporation process, for example, on the surface of a base material on which tracks with spiral lands or grooves are arranged. In writing data on such a rewritable optical disk, data is written there by irradiating the optical disk with a light beam, of which the optical power has been changed according to the data to be written, and locally changing the property of the recording material film.

It should be noted that the depth of the pits, the depth of the tracks, and the thickness of the recording material film are all smaller than the thickness of the optical disk base material. For that reason, those portions of the optical disk, where data is stored, define a two-dimensional plane, which is sometimes called an “information storage plane”. However, considering that such an “information storage plane” actually has a physical dimension in the depth direction, too, the term “information storage plane” will be replaced herein by another term “information layer”. Every optical disk has at least one such information layer. Optionally, a single information layer may actually include a plurality of layers such as a phase-change material layer and a reflective layer.

To read data that is stored on a recordable optical disk or to write data on such an optical disk, the light beam always needs to maintain a predetermined converging state on a target track on an information layer. For that purpose, a “focus control” and a “tracking control” are required. The “focus control” means controlling the position of an objective lens perpendicularly to the information storage plane (which direction will be referred to herein as a “substrate depth direction”) such that the focus position of the light beam is always located on the information layer. On the other hand, the “tracking control” means controlling the position of the objective lens along the radius of a given optical disk (which direction will be referred to herein as a “disk radial direction”) such that the light beam spot is always located right on a target track.

Various types of optical disks such as DVD (digital versatile disc)-ROM, DVD-RAM, DVD-RW, DVD-R, DVD+RW and DVD+R have become more and more popular these days as storage media on which a huge amount of information can be stored at a high density. Meanwhile, CDs (compact discs) are still popular now. Currently, next-generation optical disks, including Blu-ray disc (BD), which can store an even greater amount of information at a much higher density than any of these optical disks, are under development, and some of them have already been put on the market.

To read and write data from/on any of these optical disks, an optical head unit, including a semiconductor laser diode (LD) as a light source, is used. The semiconductor laser is driven by a semiconductor laser driver, which is a device for supplying current needed for laser oscillation to the semiconductor laser.

The semiconductor laser driver includes an automatic power control (APC) circuit for controlling the emission output of the semiconductor laser to keep the power constant. A portion of the light that has been emitted from the semiconductor laser is incident on a photodetector such as a photodiode and the APC circuit controls drive current for the semiconductor laser based on the output signal of this photodetector.

Currently, a technique for superposing RF current on direct current is adopted to drive a semiconductor laser. Such RF current is superposed to reduce the return light noise that would be produced at the semiconductor laser when the laser beam that has been reflected from an optical disk returns to the semiconductor laser.

FIG. 1 is a graph schematically showing the relation between drive current I for a semiconductor laser and optical power P (i.e., a current-optical power characteristic represented by a L/I curve). As the drive current I increases beyond its threshold value I_{TH}, the optical power P increases substantially proportionally to the increase in the drive current I. However, if the drive current I is direct current, the optical power P will be constant. In the example shown in FIG. 1, if the drive current is direct current with magnitude I₀, the optical power is P₀. If an RF current I_{H}=I₁·sin(2 πft) is superposed on such direct current I₀, then the magnitude I of the overall drive current supplied to the semiconductor laser is given by the following Equation (1).

I=I₀+I_{H}=I₀+I₁·sin(2πft) (1)

f is the frequency and t is the time. The frequency f of the RF current I_{H} will sometimes be referred to herein as a “superposed frequency”. If the drive current I is represented by Equation (1), then the optical power P will be given by the following Equation (2).

P=P₀+P_{H}=P₀+P₁·sin(2πft) (2)

P_{H} is the RF component of the optical power P and P₁ is the amplitude of the RF component P_{H}.

The return light noise is a phenomenon that arises because the oscillation mode of the semiconductor laser is a single mode. That is to say, when the light that has been reflected from an optical disk returns to the semiconductor laser, the oscillation state is disturbed in the semiconductor laser to cause mode hopping and other phenomena that would produce noise. However, if the RF current is superposed on the drive current for the semiconductor laser oscillating in the single mode, the oscillation mode changes from the single mode into a multi-mode, which will be much less affected by the return light.

In the prior art, the amplitude I₁ and frequency f of the RF current I_{H} have been adjusted to appropriate levels for reducing the return light noise. Techniques for adjusting the amplitude I₁ and frequency f are disclosed in the following documents but actually the frequency f was not adjusted.

Patent Document No. 1 discloses a technique for controlling the amplitude I₁ of the RF current I_{H} by extracting the amplitude P₁ of the RF component P_{H} from the optical power that changes with a variation in the temperature or any other parameter of the semiconductor laser with time and comparing the amplitude to a reference value.

Patent Document No. 2 discloses a technique for adjusting the amplitude I₁ of the RF current I_{H} such that the superposition of the RF current will not bring about read beam induced deteriorations.

To overcome a problem that the frequency f of the RF current I_{H} shifts from its setting when the environmental temperature of a semiconductor laser driver changes, Patent Document No. 3 discloses a technique for varying the frequency f of the RF current I_{H} into an arbitrary value.
Patent Document No. 1: Japanese Patent Application Laid-Open Publication No. 2002-335041
Patent Document No. 2: Pamphlet of PCT International Application Publication No. WO2004/038711
Patent Document No. 3: Japanese Patent Application Laid-Open Publication No. 2001-352124

### DISCLOSURE OF INVENTION

### Problems to be Solved by the Invention

The present inventors discovered that if the RF current was superposed on the drive current for a semiconductor laser, the relative intensity noise (RIN) of the semiconductor laser increased as the temperature of the semiconductor laser varied as will be described later. The RIN is a parameter representing the fluctuation of a laser beam with time and is given by the following equation.

RIN=10·log{(δP/P₀)2/Δf}. . . [dB/Hz]

where P₀ is the average optical power of a DC driven semiconductor laser, δ P is the fluctuation of the optical power, and Δf is the measuring bandwidth.

Generally speaking, the greater the average optical power P₀ (i.e., the higher the optical power of a semiconductor laser (which will be referred to herein as “output power”)), the smaller the RIN of the semiconductor laser tends to be. In a low output power range, most of the RIN is quantum noise (inherent noise) produced by natural light. On the other hand, in a high output power range, RIN is mostly mode hop noise (i.e., spectrum hopping) produced by a variation in the temperature or output of the semiconductor laser.

FIG. 2 is a graph showing how much RIN may depend on the output power (i.e., a noise profile) in a situation where RF current is superposed on drive current for a semiconductor laser. As described above, the noise profile generally tends to decrease as the output power increases. However, it is known that if RF current is superposed on drive current for a semiconductor laser, RIN starts to increase at a particular output power to reach a local maximum value. In the example shown in FIG. 2, RIN is seen to reach its local maximum value at an optical power of around 2.7 mW. At such an output power that increases RIN locally, the superposition of the RF current would have generated a new oscillation mode and produced inherent noise. Such inherent noise is produced mainly due to relaxation oscillations of the semiconductor laser.

In an optical head unit, the semiconductor laser is preferably designed to operate at an output power that will result in a relatively low RIN. That is to say, if the RF current is superposed, the output power is preferably set so as to avoid the range in which the RIN increases locally. In an optical head unit for use in an optical information read/write apparatus such as an optical disk drive, no control is performed in such a manner as to maintain the power of the laser beam that is actually emitted from the semiconductor laser (i.e., the output power) within a predetermined range. Instead, a control is carried out so as to maintain the intensity of the laser beam on the information layer of the optical disk (i.e., the read power) at a predetermined value. However, this read power is not equal to the power of the laser beam that is actually emitted from the semiconductor laser (i.e., the output power). That is why even if read power of the same level were achieved on the information layer of the optical disk, the output power would still vary with the optical efficiency (or transmission efficiency) of the optical head unit. Hereinafter, the reason will be described more fully.

In an optical head unit, the laser beam emitted from the semiconductor laser is transmitted through optical members such as a beam splitter, a collimator lens, and an objective lens and then converged on an information layer of the optical disk. The “transmission efficiency” of such an optical head unit will change with the angle of divergence of the laser beam emitted from the semiconductor laser and with the light input efficiencies and transmittances of respective optical members of the optical head unit. That is why even between optical head units of the same design, the “transmission efficiency” would vary by about 14 to 22% due to a misalignment between those optical members during the manufacturing process, for example. To achieve a read power of 0.25 mW on the information layer of the optical disk, supposing the transmission efficiency is 14%, an output power of 0.25/0.14=1.8 mW would be required. On the other hand, if the transmission efficiency is 22%, a read power of 0.25 mW will be achieved with an output power of 1.1 mW (=0.25/0.22).

As can be seen, even if the read power of the optical head units is controlled at a constant value of 0.25 mW, for example, the output powers of their semiconductor lasers will vary significantly within the range of 1.1 mW to 1.8 mw, for example, due to a difference in transmission efficiency between the respective optical head units. As a result, even if the semiconductor lasers used are of the same type, the respective optical head units will have various RINs.

Meanwhile, it is also known that if the temperature of a semiconductor laser changes, then the noise profile shifts. FIG. 3 is a graph showing noise profiles at temperatures of 25° C. and 70° C. When the output power falls within the range of 1.5 W to 3.0 W, the RIN becomes the smallest at an output power of approximately 2.0 W at 25° C. but the output power that minimizes the RIN at 70° C. shifts to approximately 2.5 W. If the temperature rises from 25° C. to 70° C. at an output power of 2.0 W, the RIN increases by much as 3 dB. In this manner, if the RIN of a semiconductor laser increases in an optical head unit, the jitter and other read performances will deteriorate.

As can be seen from the foregoing description, even if the semiconductor laser and optical system of an optical head unit are designed and adjusted so as to minimize the RIN at room temperature, the RIN could still increase significantly due to a variation in temperature during its operation, thus possibly decreasing the reliability of an optical information read/write apparatus, which is a serious problem.

In order to overcome the problems described above, the present invention has an object of providing a semiconductor laser driver that can maintain a sufficiently low RIN even if the temperature of the semiconductor laser has changed. Another object of the present invention is to provide an optical head unit and an optical information read/write apparatus including such a semiconductor laser driver.

### Means for Solving the Problems

A semiconductor laser driver according to the present invention includes: an RF superposition circuit for superposing RF current on drive current for a semiconductor laser included in an optical head unit; and RF superposition control means for controlling the frequency of the RF current according to the temperature of the semiconductor laser.

In one preferred embodiment, the RF superposition control means increases or decreases the frequency of the RF current so as to reduce the relative intensity noise of the semiconductor laser.

In another preferred embodiment, the semiconductor laser driver further includes: a temperature sensor for detecting the temperature of the semiconductor laser; and a memory for storing data about the temperature that has been detected by the temperature sensor and the frequency of the RF current. The RF superposition control means controls the RF superposition circuit based on the data stored in the memory and the temperature that has been detected by the temperature sensor.

In this particular preferred embodiment, the data includes information that defines a relation between the temperature of the semiconductor laser and the frequency of the RF current that minimizes the relative intensity noise of the semiconductor laser at that temperature.

An optical head unit according to the present invention includes: a semiconductor laser for emitting a light beam; an objective lens for converging the light beam on an information layer of an optical disk; and a semiconductor laser driver for driving the semiconductor laser. The semiconductor laser driver includes an RF superposition circuit for superposing RF current on drive current for the semiconductor laser, and RF superposition control means for controlling the frequency of the RF current according to the temperature of the semiconductor laser.

An optical information read/write apparatus according to the present invention includes: a motor for rotating an optical disk; an optical head unit including a semiconductor laser for emitting a light beam and an objective lens for converging the light beam, emitted from the semiconductor laser, on an information layer of the optical disk; a semiconductor laser driver for driving the semiconductor laser; and a read/write circuit for exchanging data with the optical disk by way of the optical head unit. The apparatus further includes an RF superposition circuit for superposing RF current on drive current for the semiconductor laser, and RF superposition control means for controlling the frequency of the RF current according to the temperature of the semiconductor laser.

A semiconductor laser driving method according to the present invention is a method for driving a semiconductor laser included in an optical head unit. The method includes: generating direct current to be supplied to the semiconductor laser; superposing RF current on the direct current; and controlling the frequency of the RF current according to the temperature of the semiconductor laser so as to reduce the relative intensity noise of the semiconductor laser.

### Effects of the Invention

A semiconductor laser driver according to the present invention can check the increase in noise by changing the frequencies of the RF current according to a variation in the temperature of the semiconductor laser.

### BRIEF DESCRIPTION OF DRAWINGS

FIG. 1 is a graph showing an optical output-current characteristic (L/I curve).

FIG. 2 is a graph showing a noise profile in a situation where a semiconductor laser has a temperature of 25° C.

FIG. 3 is a graph showing noise profiles in a situation where a semiconductor laser has a temperature of 25° C. and a situation where the semiconductor laser has a temperature of 70° C., respectively.

FIG. 4 is a graph showing the superposition frequency dependence of noise profiles.

FIG. 5 is a graph showing the temperature dependence of noise profiles.

FIG. 6 is a graph showing how the RIN increases as the temperature rises.

FIG. 7 is a graph showing how the RIN decreases as the superposition frequency decreases.

FIG. 8 is a graph showing how the influence of the output power on the increase or decrease of the RIN changes with the superposition frequency.

FIG. 9A is a graph showing how the superposition frequency may be changed with the temperature of a semiconductor laser according to the present invention.

FIG. 9B is a graph showing how the superposition frequency may also be changed with the temperature of a semiconductor laser according to the present invention.

FIG. 9C is a graph showing how the superposition frequency may also be changed with the temperature of a semiconductor laser according to the present invention.

FIG. 10 is a block diagram showing a preferred embodiment of a semiconductor laser driver according to the present invention.

FIG. 11 is a block diagram showing an exemplary configuration for the RF superposition circuit.

FIG. 12 illustrates a preferred embodiment of an optical head unit according to the present invention.

FIG. 13 illustrates a preferred embodiment of an optical information processor according to the present invention.

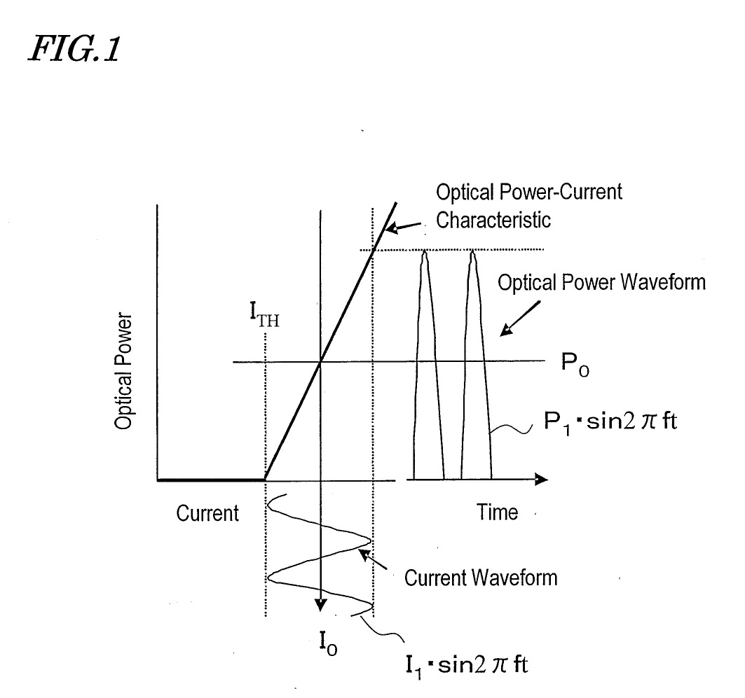

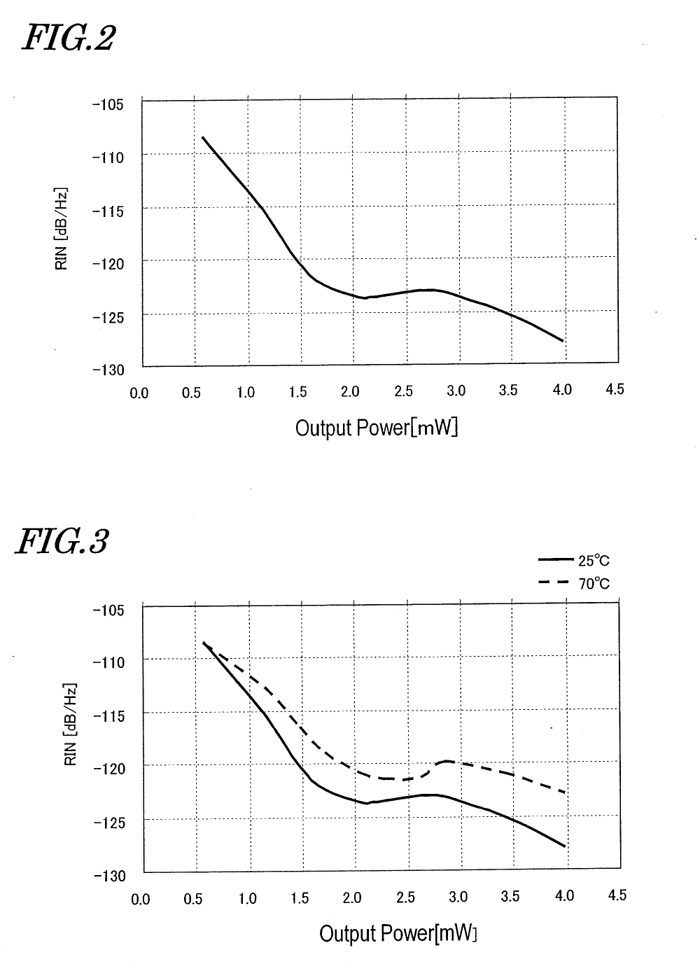

### DESCRIPTION OF REFERENCE NUMERALS

1 semiconductor laser

2 photosensor

3 RF superposition circuit

4 laser driver circuit

5 RF superposition controller

6 laser drive current

7 noise detector

8 memory device

9 temperature sensor

302 oscillation frequency changer (multi-vibrator)

304 D/A converter

306 current generator (operational amplifier)

### BEST MODE FOR CARRYING OUT THE INVENTION

The present inventors discovered that the RIN noise profile varied when the frequencies of RF superposed current were changed, thereby perfecting our invention. Before preferred embodiments of the present invention are described, it will be described first how the noise profile varies with the frequency of RF current.

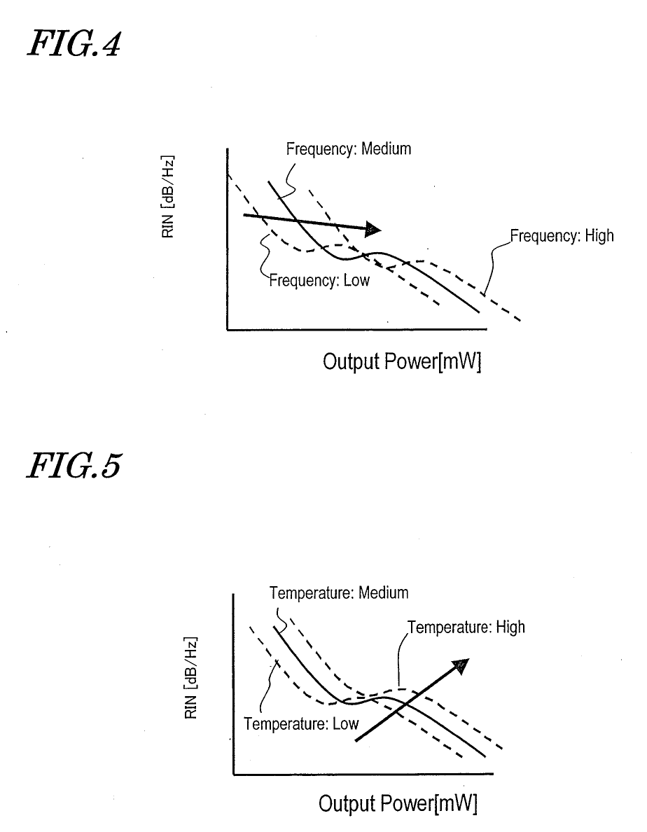

FIG. 4 is a graph schematically showing noise profiles in three situations where the superposition frequencies are low, medium and high, respectively. As the superposition frequency increases, the noise profile shifts to the right of this graph.

On the other hand, FIG. 5 is a graph schematically showing noise profiles in three situations where the temperatures of the semiconductor laser are low, medium and high, respectively, with the superposition frequency fixed. As the temperature rises, the noise profile shifts to the right of this graph.

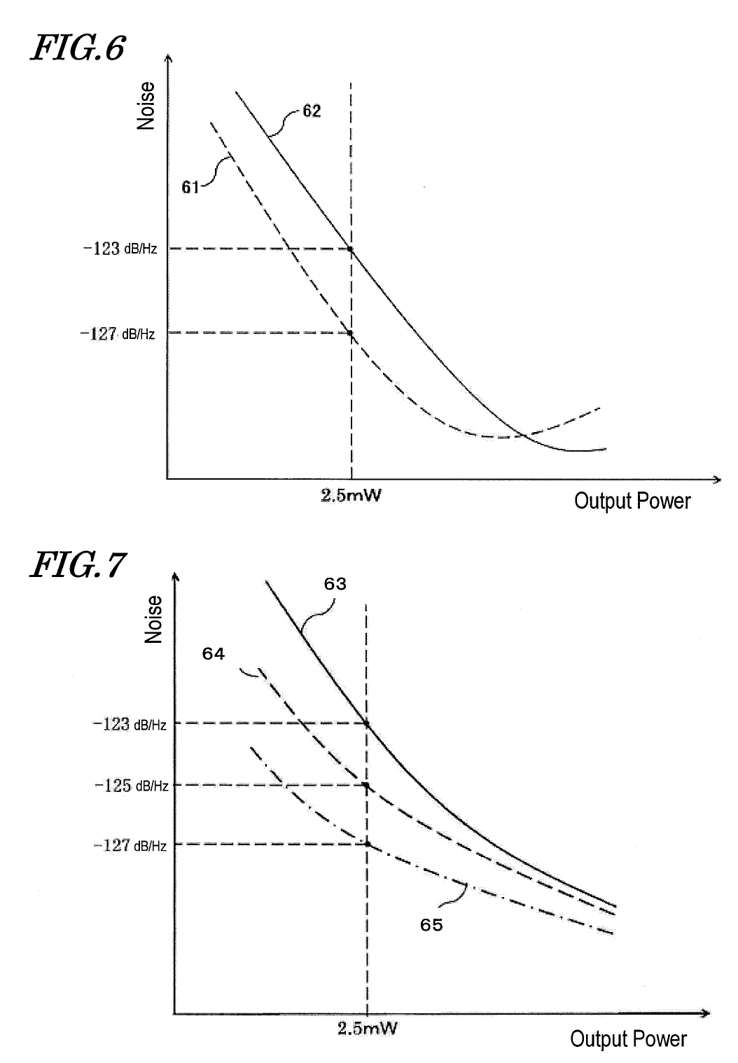

FIG. 6 shows noise profiles at output powers of around 2.5 mW in a situation where the RF current has a frequency of 400 MHz. The dashed curve 61 is a noise profile in a situation where the semiconductor laser has a temperature of 25° C., while the solid curve 62 is a noise profile in a situation where the semiconductor laser has a temperature of 60° C. At a temperature of 25° C., the RIN at an output power of 2.5 mW is −127 dBm. If the temperature rises to 60° C., however, the RIN increases to −123 dBm.

On the other hand, FIG. 7 shows noise profiles in three situations where the superposition frequencies were varied between 400 MHz, 350 MHz and 300 MHz with the temperature of the semiconductor laser fixed at 60° C. The solid, dashed and one-dot-chain curves 63, 64 and 65 are noise profiles associated with superposition frequencies of 400 MHz, 350 MHz and 300 MHz, respectively.

If the semiconductor laser had a temperature of 60° C. and if the superposition frequency remained at 400 MHz, the RIN increased to −123 dBm as described above. However, if the superposition frequency was decreased to 300 MHz, the RIN also decreased to −127 dBm. As can be seen, by decreasing the superposition frequency at an output power falling within a certain range, the increase in the noise of the semiconductor laser that would otherwise be inevitable when the temperature rises can be checked.

FIGS. 6 and 7 show only a range with a relatively low output power of the noise profiles shown in FIGS. 4 and 5. In this range, the increase in RIN that would otherwise be caused when the temperature rises can be checked by decreasing the superposition frequency as described above. Depending on the magnitude of the output power of the semiconductor laser, however, the RIN could be rather increased by decreasing the frequency of the superposition frequency. Hereinafter, such a situation will be described.

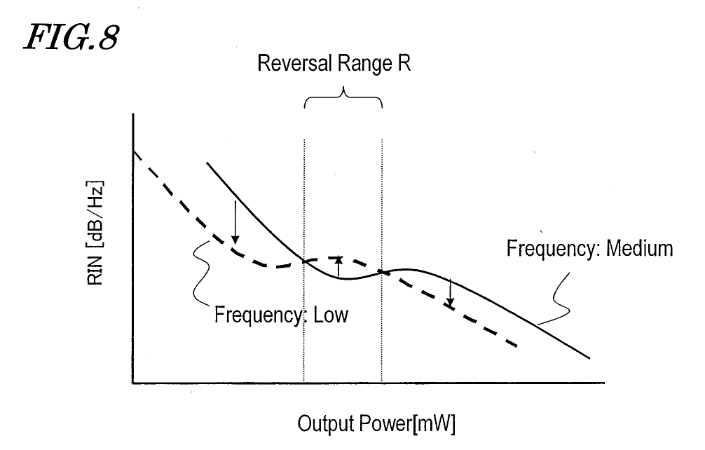

Two of the three noise profiles shown in FIG. 4, which are associated with medium and low superposition frequencies, respectively, are extracted and shown on a larger scale in FIG. 8. In any range shown in FIG. 8 but the “reversal range R”, the RIN decreases if the superposition frequency is decreased. In the reversal range R, however, if the superposition frequency is decreased, the RIN rather increases. In other words, FIGS. 6 and 7 show noise profiles in a range where the output power is lower than in the reversal range R shown in FIG. 8.

As can be seen, it depends on the output power of the semiconductor laser how the RIN changes with the frequency of the RF current, and this output power varies according to the transmission efficiency of each optical head unit as described above.

The read power of an optical head unit is measured by a photosensor and automatically controlled toward a desired value by APC based on the measured value. However, the output power of a semiconductor laser, which varies according to the transmission efficiency of each pickup unit, is not measured directly. That is why even if their read powers have been controlled to the same level, the semiconductor lasers of respective optical head units may have different output powers. It is not known, either, whether or not the output power of each semiconductor laser falls within the reversal range R shown in FIG. 8. Consequently, it depends on each specific optical head unit, and cannot be determined simply, whether the RF frequency should be increased or decreased as the temperature rises.

In a preferred embodiment of the present invention, after an optical head unit has been fabricated with a semiconductor laser actually built in, the RINs are measured with the frequency of the RF current, supplied to the semiconductor laser, varied, thereby figuring out the frequency dependence of the RIN. Besides, this measurement is carried out at multiple different temperatures (e.g., at 25° C., 50° C. and 75° C.), and the frequency that will result in the lowest RIN is determined at each of these temperatures.

Data about the RINs obtained by such measurements may be stored in a memory as a table such as the following

TABLE 1

| Superposition | RIN [dB/Hz] at | RIN [dB/Hz] at | RIN [dB/Hz] at |
|---|---|---|---|
| frequency | temperature of | temperature of | temperature of |
| (MHz) | 25° C. | 50° C. | 75° C. |
| 330 | −124.5 | −123.0 | −124.5 |
| 340 | −124.0 | −123.5 | −125.0 |
| 350 | −123.5 | −124.0 | −124.5 |
| 360 | −123.0 | −124.5 | −124.0 |
| 370 | −123.5 | −125.0 | −123.5 |
| 380 | −124.0 | −124.5 | −123.0 |
| 390 | −124.5 | −124.0 | −122.5 |
| 400 | −125.0 | −123.5 | −122.0 |
| 410 | −124.5 | −123.0 | −121.5 |
| 420 | −124.0 | −122.5 | −121.0 |
| 430 | −123.5 | −122.0 | −120.5 |

By carrying out those measurements, the superposition frequencies that will minimize the RINs can be obtained at temperatures of 25° C., 50° C. and 75° C. Suppose the superposition frequencies that will minimize the RINs at temperatures of 20° C., 50° C. and 75° C. have turned out to be 400 MHz, 370 MHz and 340 MHz, respectively. In actually operating an optical information read/write apparatus using such an optical head unit, the superposition frequency may be defined at 400 MHz based on the measurement data described above when the semiconductor laser has a temperature of 25° C. But when the temperature of the semiconductor laser rises to reach 50° C., the superposition frequency may be changed into 370 MHz. And when the temperature reaches 75° C., the superposition frequency may be further changed into 340 MHz.

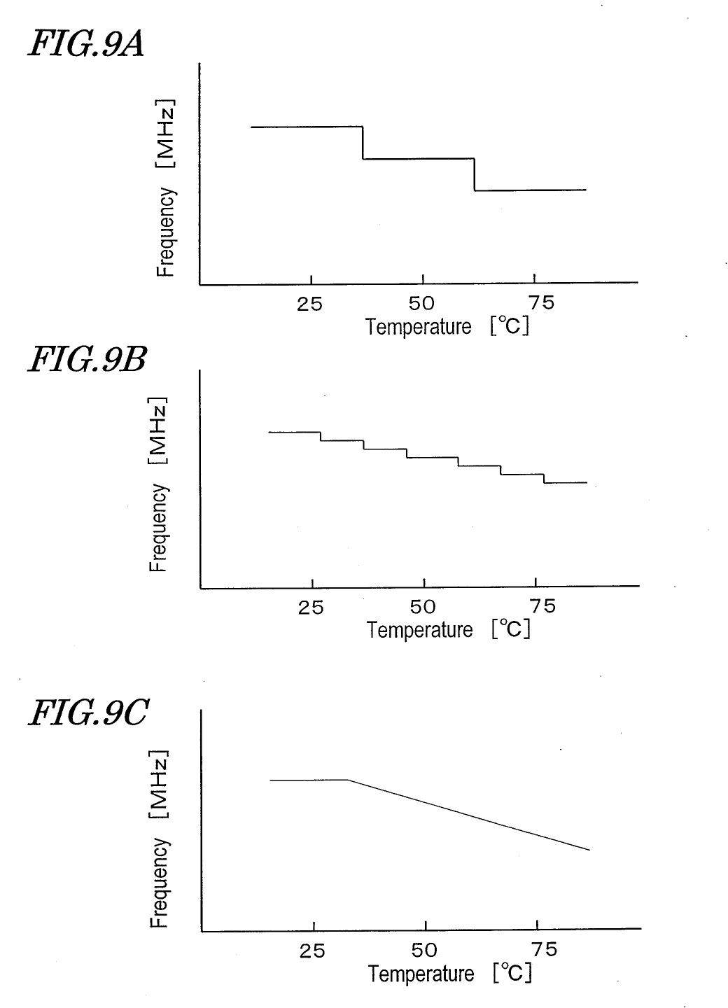

Such a control of the superposition frequency according to a variation in temperature may be carried out in various manners as shown in FIGS. 9A, 9B and 9C. In the examples shown in FIGS. 9A, 9B and 9C, the superposition frequency is decreased monotonically as the temperature rises. According to the magnitude of the output power, however, the superposition frequency should be increased monotonically as the temperature rises or the superposition frequency that has been increasing (or decreasing) should start to decrease (or increase) at a particular temperature. It is determined based on the data shown in Table 1 exactly how to change the superposition frequency.

The measurements to obtain the data shown in Table 1 are carried out with the semiconductor laser actually built in the optical head unit. Thus, data representing a characteristic of the semiconductor laser and the transmission efficiency as defined by the optical system in the optical head unit can be obtained and the best frequency can be determined for each specific optical head unit.

Optionally, the actual measurements may be carried out only at 25° C. and the data at the other temperatures may be derived by correcting the data at 25° C. As described above, even if semiconductor lasers of the same type are used, the output power could still vary from one optical head unit to another due to a difference in the transmission efficiency of light. However, once the frequency that will result in a local minimum RIN has been obtained by actually performing measurements at a particular temperature (e.g., 25° C.), the frequencies that will result in local minimum RINs at the other temperatures can be estimated based on the characteristic of the semiconductor laser.

Also, if the real temperatures T of the semiconductor laser during its actual operation are not equal to any of 25° C., 50° C. and 75° C., then the frequency that will minimize the RIN at the temperature T may be calculated based on the data shown in Table 1. Temperature variations such as those shown in FIGS. 9B and 9C are easily realized if interpolated data is figured out based on the measurement data at 25° C. 50° C. and 75° C. shown in Table 1.

It should be noted that the data shown in Table 1 was obtained when a particular read power was realized on the information layer of an optical disk. However, if the read power is different, then the output power will vary accordingly, and therefore, data with different numerical values from those shown in Table 1 will be obtained. To play multiple different types of optical disks with respectively different read powers, the data shown in Table 1 may be collected for each of the multiple different read powers and stored in a memory.

Hereinafter, a preferred embodiment of a semiconductor laser driver according to the present invention will be described.

### EMBODIMENT 1

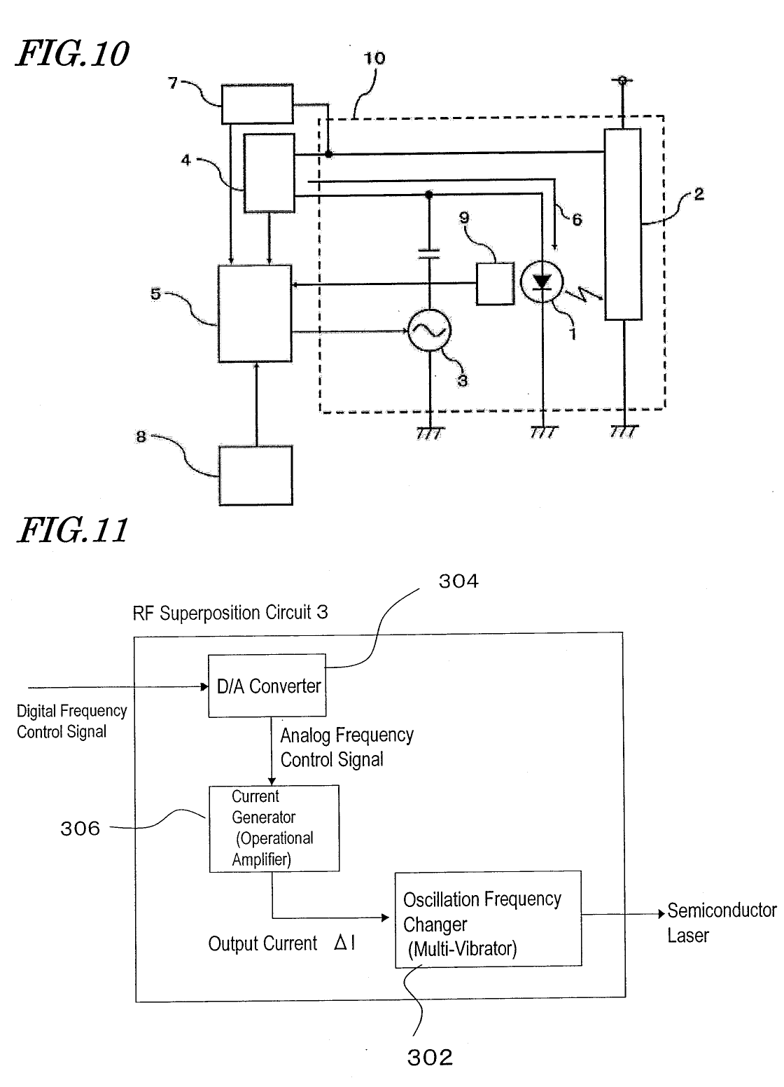

FIG. 10 shows a configuration for a preferred embodiment of a semiconductor laser driver according to the present invention.

The semiconductor laser driver of this preferred embodiment includes a semiconductor laser 1, a photosensor 2 for detecting a portion of the laser beam that has been emitted from the semiconductor laser 1, a laser driver circuit 4 for supplying DC components of laser drive current 6 to the semiconductor laser 1, an RF superposition circuit 3 for superposing RF current on the DC components of the laser drive current 6, an RF superposition controller 5 for controlling the operation of the RF superposition circuit 3, a temperature sensor 9 for sensing the temperature of the semiconductor laser 1, a noise detector 7 for detecting the noise (i.e., RIN in this case) of the semiconductor laser 1, and a memory device 8 that stores various types of data such as that shown in Table 1.

The main section 10 of this semiconductor laser driver consists of the elements inside the dashed square in FIG. 10 and is built in an optical head unit. Some elements of the semiconductor laser driver may be arranged on the circuit board of an optical information read/write apparatus, which is located outside of the optical head unit. For example, the RF superposition controller 5 is typically included in an integrated circuit (IC) that has been mounted on the circuit board of the optical information read/write apparatus. However, the RF superposition controller 5 may also be included in a laser drive IC in the optical head unit. Meanwhile, the laser driver circuit 4 is typically built in the laser drive IC in the optical head unit.

The optical head unit actually further includes an objective lens for converging the laser beam that has been emitted from the semiconductor laser 1 and a photodetector for detecting the light that has been reflected from the optical disk. However, these elements are well known in the art and are not shown in FIG. 10.

The semiconductor laser 1 is a single-mode laser with an oscillation wavelength of 405 nm, for example, and emits a laser beam with a power to be determined by the laser drive current 6 supplied from the laser driver circuit 4. A portion of the laser beam that has been emitted from the semiconductor laser 1 is incident on the photosensor 2, where the light is converted into an electrical signal representing the intensity of the incident light by photoelectric conversion. This electrical signal is fed back to the laser driver circuit 4, which keeps the output of the photosensor 2 constant in order to control the read power at a predetermined value. That portion of the laser beam to be measured in order to regulate the output power of the semiconductor laser 1 is generally called “front light” and the photosensor 2 to detect the front light is called a “front light monitor”.

Most of the laser beam that has been emitted from the semiconductor laser 1 is directed toward an optical disk through an objective lens (not shown) to perform a read or write operation and irradiates the information layer of the disk. The light that has been reflected from the information layer of the optical disk will be incident on a photodetector (not shown), where the light is converted photoelectrically to generate various types of signals.

The DC drive current to be output from the laser driver circuit 4 is controlled such that the output electrical signal of the photosensor 2 has a constant average with time (i.e., DC component). That is why the average of the output power of the semiconductor laser 1 is kept substantially constant.

The RF superposition circuit 3 superposes an RF signal on the DC components of the laser drive current 6. FIG. 11 shows an exemplary configuration for the RF superposition circuit 3, which includes an oscillation frequency changer (multi-vibrator) 302, a D/A converter 304, and a current generator (operational amplifier) 306. The multi-vibrator 302 is an oscillator that oscillates at a variable RF frequency of about 200 MHz to about 600 MHz. The D/A converter 304 converts the frequency control signal supplied from the RF superposition controller 5 from a digital signal into an analog one and passes the analog signal to the operational amplifier 306. In response, the operational amplifier 306 generates a current ΔI, of which the magnitude is defined by the frequency control signal, and supplies the current to the multi-vibrator 302. When the magnitude of the current ΔI changes, the voltage between the two terminals of a resistor, included in the multi-vibrator 302, varies, thus causing a variation in oscillation frequency (superposition frequency).

The RF current that has been output from the RF superposition circuit 3 is superposed on the laser drive current 6 by AC coupling. Then, the laser drive current 6, on which the RF current has been superposed, is injected into the semiconductor laser 1, thereby causing the single-mode laser 1 to produce multi-mode emission of light. As a result, the influence of the light that has returned from a storage medium such as an optical disk can be reduced, and eventually, the noise can be cut down.

It should be noted that in performing a write operation on the optical disk, the optical power is increased compared to a read operation and recording gets done by causing a phase change in the information layer of the optical disk, which may be made of a phase change material, for example. In the recording mode, the laser driver circuit 4 functions so as to increase the laser drive current 6 and eventually the optical power.

The memory device 8 may be a semiconductor memory, for example, and may store information about how much the frequency of the RF current should be increased or decreased when the temperature of the semiconductor laser 1 changes as a table in which the temperature is associated with the superposition frequency as described above.

The temperature sensor 9 measures the temperature of the semiconductor laser 1 and outputs an electrical signal representing the temperature measured. The RF superposition controller 5 controls the RF frequency being output from the RF superposition circuit 3 by reference to the information stored in the memory device 8 with the temperature of the semiconductor laser 1 that has been sensed by the temperature sensor 9, thereby checking the increase in noise in the semiconductor laser 1.

When the temperature of the semiconductor laser 1 rises, the RIN increases. However, by adjusting the RF frequency to be superposed for the semiconductor laser 1 according to the temperature that has been sensed by the temperature sensor 9, the increase in RIN can be minimized.

It should be noted that the read power also changes according to the type of the optical disk to play. For example, if a read power for a single-layer BD disc is about 0.25 mW, a read power for a dual-layer BD disc will be about 0.50 mW. If the read power required changes according to the type of the given optical disk in this manner, the output power of the semiconductor laser should also be changed accordingly.

In this preferred embodiment, to control the output power of the semiconductor laser to such a range in which the RIN decreases sufficiently by the method described above, the frequency of the RF current is adjusted. However, the data used for that purpose has been obtained under such conditions as to achieve a desired read power. Even optical head units of the same type will have different output powers if the read powers are different. For that reason, the frequency that will minimize the RIN at each temperature will also change.

Such a problem may be overcome by one of the following two methods.

(1) Data such as that shown in Table 1 about the read powers of respective types of optical disks to play is collected and stored in the memory. After the read power has been determined by the type of the optical disk that has been loaded into the optical information read/write apparatus, data associated with that read power is read and the frequency is optimized.

(2) The output power of the semiconductor laser may be kept from changing even if the read power has changed according to the type of the given optical disk. For instance, in the example described above, if the read power is defined at 0.5 mW, which is adequate for a dual-layer BD, best frequencies for respective temperatures are determined in advance. And if the optical information read/write apparatus is loaded with a single-layer BD, an optical power control device for adjusting the intensity of the laser beam that has been emitted from the semiconductor laser is inserted into the optical path, thereby reducing the read power to about 0.25 mW. The read power is changed by the optical power control device. That is why even if the read power needs to be changed, the output power of the semiconductor laser can still be kept substantially constant. Then, the best frequency may be selected based on the data that has been acquired for a particular read power and read powers for various types of optical disks are realized at low RINs.

Generally speaking, even in optical disks other than BDs, a single-layer disk needs a lower read power than a dual-layer disk, and there would be no problem even if the transmission efficiency of the optical head unit were decreased. Thus, in playing a single-layer disk, the transmission efficiency of the optical head unit is intentionally halved by inserting a filter with a transmittance of 50% (which is called a “dimming filter”), for example, onto the optical path. Consequently, since the output power of the semiconductor laser can still be kept rather high even when the read power needs to be decreased, RINs can be reduced.

### EMBODIMENT 2

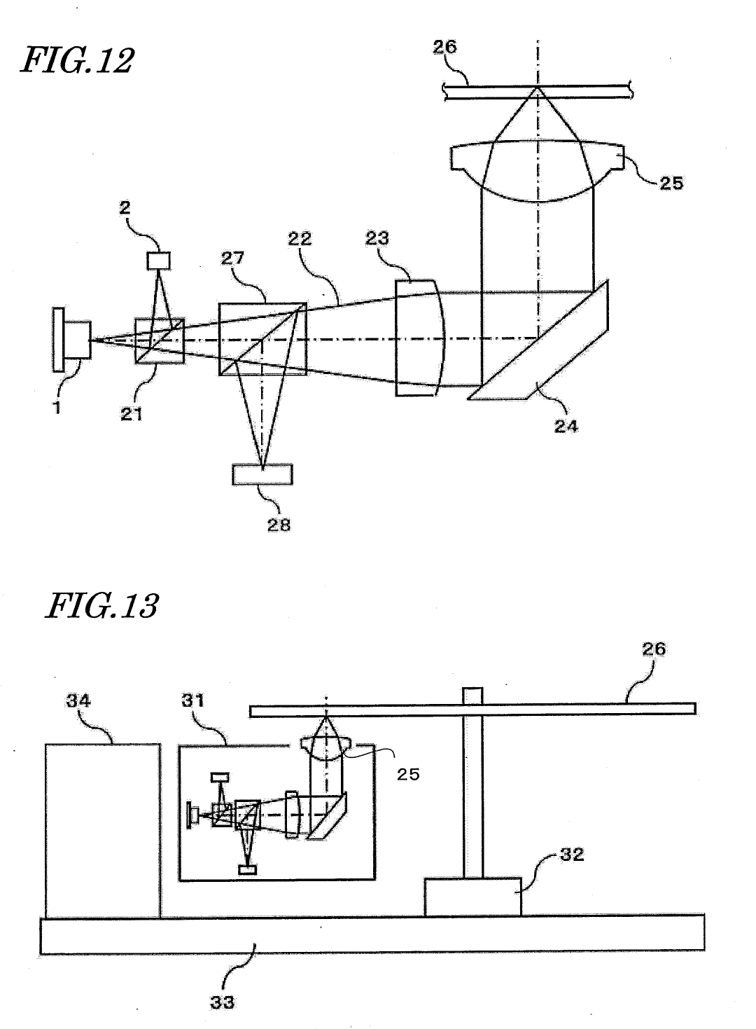

Hereinafter, a preferred embodiment of an optical head unit according to the present invention will be described with reference to FIG. 12. In FIG. 12, any member having substantially the same function as the counterpart shown in FIG. 10 is identified by the same reference numeral.

The optical head unit of this preferred embodiment is characterized by including the semiconductor laser driver of the first preferred embodiment described above.

In the optical head unit of this preferred embodiment, the laser beam 22 that has been emitted with a wavelength of 405 nm from the semiconductor laser 1 is transformed by a condenser lens 23 into a substantially parallel beam, which is then directed by a standup mirror 24 toward an objective lens 25. In response, the objective lens 25 converges the laser beam 22 onto an information layer of an optical disk 26. The light is reflected from the information layer of the optical disk 26 and then goes back in the opposite direction by passing through the objective lens 25, standup mirror 24 and objective lens 23 in this order. The reflected light is reflected by a beam splitter 27 and then incident on a photodetector 28, where the light is converted photoelectrically into an electrical signal. This electrical signal is used to generate an RF signal or a servo signal based on the pit sequence on the optical disk 26.

Meanwhile, a portion of the laser beam 22 that has been emitted from the semiconductor laser 1 is separated by a front light monitoring beam splitter 21 and incident on the photosensor 2. As already described for the first preferred embodiment, the output electrical signal of the photosensor 2 has been converted photoelectrically so as to represent the intensity of the incoming light. This electrical signal is fed back to the laser driver circuit 4 of the semiconductor laser driver shown in FIG. 10 and used to control the laser beam emission intensity (i.e., the output power) of the semiconductor laser 1.

In reading and writing data, the optical head unit operates basically in the same way. In writing data, however, the optical power of the light that has been emitted from the semiconductor laser 1 is relatively high. And data is written by changing the optical property of the information layer of the optical disk 26.

The optical head unit of this preferred embodiment includes the semiconductor laser driver of the first preferred embodiment, and therefore, can adjust the frequency of the RF current appropriately with a variation in the temperature of the semiconductor laser 1. As a result, the generation of noise can be minimized and the read and/or write operation(s) can be performed with stability.

### EMBODIMENT 3

Hereinafter, a preferred embodiment of an optical information processor according to the present invention will be described with reference to FIG. 13.

The optical information processor of this preferred embodiment is an optical disk drive that can read and/or write data from/on an optical disk, and is characterized by including the optical head unit of the second preferred embodiment described above.

The optical information read/write apparatus of this preferred embodiment includes the optical head unit 31 of the second preferred embodiment, a motor 32 for rotating the optical disk 26, a power supply unit 34 for supplying power to the optical head unit 31 and the motor 32, and a circuit board 33 connected to these members. On the circuit board, arranged are a circuit for controlling the operation of the optical head unit 31 and a circuit for performing signal processing that needs to get done to read and write data from/on the optical disk 26. These circuits are implemented as integrated circuits and integrated together on the circuit board 33.

The optical head unit 31 sends a signal representing its position with respect to the optical disk 26 to the circuit board 33. In response to this signal, the circuit board 33 outputs servo signals to drive the optical head unit 31 and the objective lens 25 in the optical head unit 31. While subjected to focus servo and tracking servo controls by a drive mechanism (not shown), the optical head unit 31 and the objective lens 25 perform the operation of reading, writing or erasing information from/on the optical disk 26. The power supply unit 34 supplies power to the circuit board 33, the drive mechanism for the optical head unit 31, the motor 32 and the objective lens driver.

The optical information read/write apparatus of this preferred embodiment includes the optical head unit 31 of the second preferred embodiment described above, and can check increase in RIN by changing the frequencies of the RF current appropriately with a variation in the temperature of the semiconductor laser 1 in the optical head unit 31. Consequently, even if the temperature of the semiconductor laser rises, the optical information read/write apparatus of this preferred embodiment can minimize the generation of noise and can perform read and/or write operations with good stability.

### INDUSTRIAL APPLICABILITY

A semiconductor laser driver according to the present invention can check increase in noise in a semiconductor laser due to a temperature variation, and therefore, is applicable extensively to any apparatus including a semiconductor laser that needs to operate with low noise.

1. A semiconductor laser driver comprising:
an RF superposition circuit for superposing RF current on drive current for a semiconductor laser included in an optical head unit; and
RF superposition control means for controlling the frequency of the RF current according to the temperature of the semiconductor laser.

2. The semiconductor laser driver of claim 1, wherein the RF superposition control means increases or decreases the frequency of the RF current so as to reduce the relative intensity noise of the semiconductor laser.

3. The semiconductor laser driver of claim 1, further comprising:
a temperature sensor for detecting the temperature of the semiconductor laser; and
a memory for storing data about the temperature that has been detected by the temperature sensor and the frequency of the RF current,
wherein the RF superposition control means controls the RF superposition circuit based on the data stored in the memory and the temperature that has been detected by the temperature sensor.

4. The semiconductor laser driver of claim 3, wherein the data includes information that defines a relation between the temperature of the semiconductor laser and the frequency of the RF current that minimizes the relative intensity noise of the semiconductor laser at that temperature.

5. An optical head unit comprising:
a semiconductor laser for emitting a light beam;
an objective lens for converging the light beam on an information layer of an optical disk; and
a semiconductor laser driver for driving the semiconductor laser,
wherein the semiconductor laser driver includes
an RF superposition circuit for superposing RF current on drive current for the semiconductor laser, and
RF superposition control means for controlling the frequency of the RF current according to the temperature of the semiconductor laser.

6. An optical information read/write apparatus comprising:
a motor for rotating an optical disk;
an optical head unit including a semiconductor laser for emitting a light beam and an objective lens for converging the light beam, emitted from the semiconductor laser, on an information layer of the optical disk;
a semiconductor laser driver for driving the semiconductor laser; and
a read/write circuit for exchanging data with the optical disk by way of the optical head unit,
wherein the apparatus further includes:
an RF superposition circuit for superposing RF current on drive current for the semiconductor laser, and
RF superposition control means for controlling the frequency of the RF current according to the temperature of the semiconductor laser.

7. A method for driving a semiconductor laser included in an optical head unit, the method comprising:
generating direct current to be supplied to the semiconductor laser;
superposing RF current on the direct current; and
controlling the frequency of the RF current according to the temperature of the semiconductor laser so as to reduce the relative intensity noise of the semiconductor laser.
